(19) United States
(12) Patent Application Publication
(10) Pub. No.: US 2006/0197191 A1
(43) Pub. Date: Sep. 7, 2006

(54) CHIP STRUCTURE AND WAFER STRUCTURE

(76) Inventors: Mon-Chin Tsai, Kaohsiung (TW); Chi-Yu Wang, Kaohsiung City (TW); Jian-Wen Lo, Taipei County (TW); Shao-Wen Fu, Pingtung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,970

(22) Filed: Dec. 13, 2005

(30) Foreign Application Priority Data
Feb. 3, 2005 (TW) 94103332

(51) Int. Cl. H01L 23/58

(52) U.S. Cl. 257/640

(57) ABSTRACT

A chip structure comprising a substrate, a circuitry unit, a plurality of bonding pads, a first passivation layer and a redistribution layer is provided. The circuitry unit is disposed on the substrate, and the bonding pads are disposed on the circuitry unit. Moreover, the first passivation layer is disposed on the circuitry unit and exposes the bonding pads. The redistribution layer of a Ti/Cu/Ti multi-layered structure is disposed on the first passivation layer, and is electrically connected with the bonding pads. In addition, the redistribution layer of a Ti/Cu/Ti multi-layered structure has excellent conductivity such that electrical characteristics of the chip structure are enhanced effectively.

### CROSS-REFERENCE TO RELATED APPLICATION

This application claims the priority benefit of Taiwan application serial no. 94103332, filed on Feb. 3, 2005. All disclosure of the Taiwan application is incorporated herein by reference.

### BACKGROUND OF THE INVENTION

1. Field of the Invention

The present invention relates to a chip structure and a wafer structure, and more particularly to a chip structure and a wafer structure with excellent electrical characteristics.

2. Description of the Prior Art

Today in the highly informationized society, the market of multimedia applications continues to extend rapidly. Integrated circuit packaging technology needs to meet the requirements of the electronic devices in digitalization, networking, localized connection and humanized applications. In order to achieve the above requirements, various demands including high-speed processing, multi-functioning, integration, miniature and light weight and low prices have to be strengthened for the electronic components. Therefore, the integrated circuit packaging technology also develops towards miniature and compactness. The so-called integrated circuit packaging density refers to the amount of pins contained in a unit area. For the high density integrated circuit packaging, shortening the length of the wiring between the integrated circuit and the packaging substrate will help to increase the speed of signal transmission. Hence, flip chip packaging technology which uses the bump for connection has become the mainstream of the high density packaging.

Taking the most common wire bonding chip as an example, the bonding pads thereon are typically of the peripheral type, and are electrically connected to the wire bonding pads on the package substrate through wires. On the other hand, the bonding pads on the flip chip are arranged in an array type, and are electrically connected to the bump bonding pads on the packaging substrate through bumps. As the flip chip packaging technology has gradually become the mainstream trend, more and more products will be packaged by flip chip technology. However, modifying the chip design of the existing products to match the packaging type is rather uneconomic. Therefore, the redistribution technology of bonding pads has been developed. The redistribution technology redistributes the peripheral distribution type of bonding pads on the wire bonding chip into the array type of the bonding pads of flip chips for disposing the bumps by disposing a redistribution layer (RLD) on the surface of the original wire bonding chip.

However, the conventional redistribution layer is formed by a single-layered aluminum (Al) structure. Since the conductivity of Al is poor, the electrical characteristics of the chips where the material of the redistribution layer is aluminum are accordingly inferior.

### SUMMARY OF THE INVENTION

Based on the above description, the object of the present invention is to provide a chip structure, which has excellent electrical characteristics.

Another object of the present invention is to provide a wafer structure, which has excellent electrical characteristics.

The present invention provides a chip structure comprising a substrate, a circuitry unit, a plurality of bonding pads, a first passivation layer and a redistribution layer. The circuitry unit is disposed on the substrate, and the bonding pads are disposed on the circuitry unit. Moreover, the first passivation layer is disposed on the circuitry unit and exposes the bonding pads. The redistribution layer composed of Ti/Cu/Ti is disposed on the first passivation layer, and is electrically connected with the bonding pads.

According to the preferred embodiment of the present invention, the chip structure described above, for example, further comprises a second passivation layer which is disposed on the first passivation layer and the redistribution layer and exposes a part of the redistribution layer. The material of the second passivation layer is, for example, polyimide (PI) or benzocyclobutene (BCB).

According to the preferred embodiment of the present invention, the chip structure, for example, further comprises a plurality of under-ball metal (UBM) layers and a plurality of bumps. The under-ball metal layers are disposed on the redistribution layer exposed by the second passivation layer, and each under-ball metal layer is composed of, for example, Al/Ni—V alloy/Cu. Moreover, each bump is respectively disposed on one of the under-ball metal layers.

According to the preferred embodiment of the present invention, the material of first passivation layer described above is, for example, silicon dioxide or silicon nitride.

The present invention further provides a wafer structure comprising a substrate, a plurality of circuitry units, a plurality of bonding pads, a first passivation layer and a redistribution layer. The circuitry units are disposed on the substrate, and the bonding pads are respectively disposed on the circuitry units. Moreover, the first passivation layer is disposed on the circuitry units and the bonding pads are exposed. Additionally, the redistribution layer is disposed on the first passivation layer and is electrically connected with the bonding pads. The redistribution layer is a multi-layered Ti/Cu/Ti structure.

According to the preferred embodiment of the present invention, the wafer structure described above further comprises a second passivation layer. The second passivation layer is disposed on the first passivation layer and the redistribution layer and exposes a part of the redistribution layer. The material of the second passivation layer is, for example, polyimide (PI) or benzocyclobutene (BCB).

According to the preferred embodiment of the present invention, the wafer structure described above, for example, further comprises a plurality of under-ball metal layers and a plurality of bumps, wherein the under-ball metal layers are disposed on the redistribution layer exposed by the second passivation layer, and each bump is disposed on one of the under-ball metal layers. Moreover, each under-ball metal layer is composed of, for example, a multi-layered structure of Al/Ni—V alloy/Cu or Ni—V alloy/Cu.

According to the preferred embodiment of the present invention, the material of the first passivation layer described above is, for example, silicon dioxide or silicon nitride.

The present invention uses the multi-layered Ti/Cu/Ti structure as the redistribution layer. Since both the upper and the lower surfaces of the copper metal layer are covered by titanium metal layers, the copper metal layer is not easily affected by moistures, thus alleviating the oxidation of copper by the moistures. Moreover, because copper has a conductivity better than that of aluminum, the electrical characteristics of the chips can be increased.

In order to the make the aforementioned and other objects, features and advantages of the present invention more comprehensible, a preferred embodiment accompanied with figures is described in detail below.

### BRIEF DESCRIPTION OF THE DRAWINGS

FIG. 1 depicts a schematic view of a wafer structure according to an embodiment of the present invention; and

FIG. 2 depicts a schematic view of a chip structure according to an embodiment of the present invention.

### DESCRIPTION OF THE EMBODIMENTS

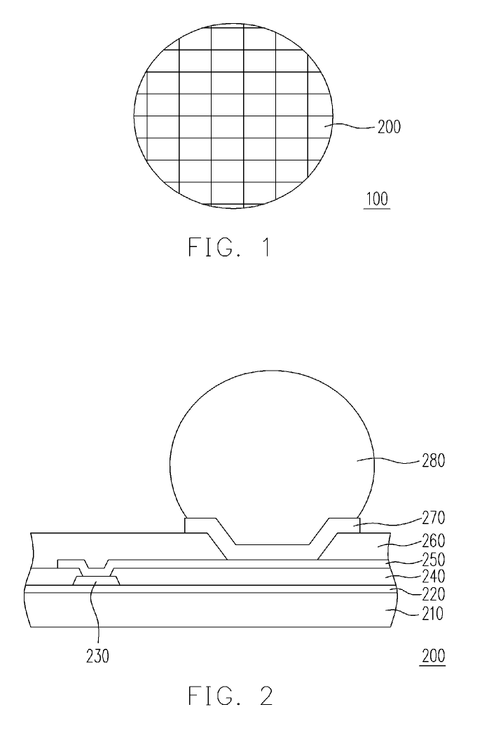

FIG. 1 depicts a schematic view of a wafer structure according to an embodiment of the present invention. Referring to FIG. 1, the wafer is typically formed by using trichlorosilane to form rod-shaped crystal silicon by thermal decomposition method. Alternatively, high-purity polysilicon grains are hot melted to a liquid state and then rod-shaped crystal silicon is formed by the floating zone or Czochralski method. Then, the rod-shaped crystal silicon is cut into slice-shaped wafers by, for example, the line cutting method. After that, the wafer 100 will go through the early stages of processing of forming integrated circuits, and then the wafer 100 will be cut into a plurality of chip structures 200.

FIG. 2 depicts a schematic view of a chip structure according to an embodiment of the present invention. Referring to FIG. 2, the chip structure 200 comprises a substrate 210, a circuitry unit 220, a plurality of bonding pads 230, a first passivation layer 240 and a redistribution layer 250. The circuitry unit 220 is disposed on the substrate 210, and the bonding pads 230 are disposed on the circuitry unit 220. Moreover, the first passivation layer 240 is disposed on the circuitry unit 220, and the first passivation layer 240 does not completely cover the bonding pads 230, with a part of the bonding pads 230 being exposed. Additionally, the redistribution layer 250 is disposed on the first passivation layer 240, and the redistribution layer 250 is electrically connected with bonding pads 230. In this embodiment, the redistribution layer 250 is composed of a Ti/Cu/Ti multi-layered structure. More particularly, the copper metal layer is disposed in the middle of the redistribution layer 250, and both the upper surface and the lower surface of the copper metal layer are covered by a titanium metal layer. While in one preferred embodiment, the material of the first passivation layer 240 can be, for example, silicon dioxide, silicon nitride, high molecular material or other insulating materials.

As described above, in this embodiment, the redistribution layer 250 is composed of a Ti/Cu/Ti multi-layered structure and due to the superior conductivity of copper, the electrical characteristics of the chips can be enhanced.

It should be noted that, in this embodiment, a second passivation layer 260 can be disposed on the redistribution layer 250 and the first passivation layer 240, and the second passivation layer 260 does not completely cover the redistribution layer 250, with a part of the redistribution layer 250 being exposed. In one preferred embodiment, the material of the second passivation layer 260, for example, can be polyimide (PI), benzocyclobutene (BCB) or other insulating materials.

As described above, in the chip structure 200 of the present invention, the chip structure 200 further comprises a plurality of under-ball metal layers 270 and a plurality of bumps 280. The under-ball metal layer 270 is disposed on the redistribution layer 250 that is exposed by the second passivation layer 260, and one bump 280 is disposed on each under-ball metal layer 270. In one preferred embodiment, the under-ball metal layer 270 is composed of, for example, an Al/Ni—V alloy/Cu multi-layered structure. More particularly, the aluminum metal layer is disposed at the bottom layer of the under-ball metal layer 270, and the Ni—V alloy layer is disposed on the aluminum layer, and the copper layer is in turn disposed on the Ni—V alloy layer. The under-ball metal layer 270 is directly contacted with the second passivation layer 260, and the aluminum layer is used as an adhesion layer.

It should be noted that copper metal is easily oxidized when in contact with moistures. However, in this embodiment, because the upper surface and the lower surface of the copper metal layer are covered with titanium metal layers for the redistribution layer 250, titanium can prevent moistures from invading into the redistribution layer 250, and avoid the oxidization of copper.

To sum up, the redistribution layer of the present invention is composed of a Ti/Cu/Ti multi-layered structure, instead of the conventional single-layered structure. Since the upper surface and the lower surface of the copper metal layer are covered by titanium metal layers in the redistribution layer, the oxidization of copper can be alleviated. Moreover, as the conductivity of copper is better than that of aluminum, the redistribution layer composed of a Ti/Cu/Ti multi-layered structure can improve the electrical characteristics of the chips.

Although the present invention is disclosed as above by preferred embodiments, they are not intended to limit the present invention. Various variations and modifications can be made by those skilled in the art without departing from the spirit and scope of the present invention, and the scope of the present invention shall be defined by the appended claims.

What is claimed is:

1. A wafer structure, comprising:
a substrate;
a plurality of circuitry units, disposed on the substrate;
a plurality of bonding pads, respectively disposed on one of the circuitry units;
a first passivation layer, disposed on the circuitry units, and exposing the bonding pads; and
a redistribution layer, disposed on the first passivation layer, wherein the redistribution layer is electrically connected with the bonding pads, and the redistribution layer is a Ti/Cu/Ti stacked structure.

2. The wafer structure as claimed in claim 1, further comprising a second passivation layer, disposed on the first passivation layer and the redistribution layer, and exposing a part of the redistribution layer.

3. The wafer structure as claimed in claim 2, wherein a material of the second passivation layer includes polyimide (PI) or benzocyclobutene (BCB).

4. The wafer structure as claimed in claim 1, further comprising:
a plurality of under-ball metal layers, disposed on the redistribution layer exposed by the second passivation layer; and
a plurality of bumps, wherein each of the bumps is disposed on one of the under-ball metal layers.

5. The wafer structure as claimed in claim 4, wherein each of the under-ball metal layers includes a Al/Ni—V alloy/Cu stacked structure or a Ni—V alloy/Cu stacked structure.

6. The wafer structure as claimed in claim 4, wherein a material of the first passivation layer includes silicon dioxide or silicon nitride.
